(19) United States
(12) Patent Application Publication
(10) Pub. No.: US 2012/0206149 A1
(43) Pub. Date: Aug. 16, 2012

(54) Method and Apparatus for Ground Distance Protection

(75) Inventors: Bin Su, Beijing (CN); Youyi Li, Beijing (CN); Ying Yang, Beijing (CN)

(73) Assignee: ABB Research Ltd., Zurich (CH)

(21) Appl. No.: 13/503,711

(22) PCT Filed: Nov. 18, 2009
(86) PCT No.: PCT/CN2009/075004

§ 371 Date: Apr. 24, 2012

(51) Int. Cl. G01R 31/12

(52) U.S. Cl. 324/509

(57) ABSTRACT

The invention relates to a ground distance protection method, which comprises: measure local source impedance based on fault component at both ends (M, N) of the transmission line in the case of a ground distance fault has occurred. Send the measured local source impedance from a first end to a second end. Adjust a protection criterion at the second end based on the measured impedance. And, judge the ground fault as an internal fault or an external fault according to the adjusted protection criterion. The invention also relates to a controller, a piece of software and an apparatus for implementing the same function.

### TECHNICAL FIELD

The invention relates to a method and apparatus for improving the performance of a ground distance protection for a power transmission system. In particular, the invention relates to such a method and apparatus which makes the reactance boundary immune to the remote in-feeding current when the system is non-homogeneous.

### BACKGROUND ART

Electric power transmission systems frequently adopt a distance relay to determine whether a fault of the system is within a predetermined distance from a particular monitoring/measuring point where the relay is located. The area within such a predetermined distance from the monitoring point is referred to as one protection zone of the relay. That is, there are several protection zones (e.g., zone 1, zone 2, zone 3 etc.) located on a transmission line sequentially. The present invention is particularly concerned with distance relays which respond to single phase to ground faults within a particular protection zone, for example, zone 1. Generally, a separate relay is normally provided in zone 1 for each phase of the poly-phase power transmission system.

In a generally adopted form of a distance relay, a tripping signal determination is made by comparing the phases of voltages derived from measurements of the system voltage and current at the monitoring point under fault conditions. For example, referring to FIG. 1, in the quadrilateral ground distance characteristic relay, it consists of four elements. As shown in FIG. 1, each side of the quadrilateral characteristic graph represents a different element. Specifically, the top line 11 represents reactance element; the right and left line, 12 and 14, respectively represents positive and negative resistance boundaries; and the bottom line 13 represents directional element. The characteristic graph shown in FIG. 1 represents the typical quadrilateral characteristic for a transmission line. A quadrilateral ground distance characteristic operates if the measured impedance falls inside the box area defined by the four elements mentioned above. If the measured impedance falls outside the box area, the relay determines that the fault is occurred outside its protection zone, and therefore, will not operate.

A system is homogeneous when the line and source angles are equal in all three sequence networks. The system is also considered as homogeneous if the source and line impedances associated with the sequence current used by the reactance element for a polarizing reference have the same angle. For example, in a reactance element that uses zero-sequence current as a polarizing reference, only consider the zero-sequence network. In a reactance element that uses negative-sequence current as a polarizing reference, only consider the negative-sequence network. In present invention, the discussion and calculation is focused on reactance elements that use zero-sequence parameter.

A system is non-homogeneous when the source and line impedance angles are not the same. In a non-homogeneous system, the angle of the total current in the fault is different from the angle of current measured at the relay. For a bolted fault (a condition that assumes no resistance in the fault), a difference between the fault current angle and the current angle measured at the relay is not a problem.

However, for the situation described in FIG. 1, where a fault resistance exists, the difference between the fault and relay current angles can cause a ground distance relay to severely under-reach or over-reach. This is particularly true in the case of a high resistance fault occurs. If this system parameter non-homogeneity is not properly corrected, the protection will either have a low sensitivity behavior (referred to as “under-reach”) or mistakenly trip with respect to a fault external to the protection zone (referred to as “over-reach”). In the situation of under-reach, an internal fault occurred within the protection zone may be regarded as an external one, and the relay therefore will not trip. In the situation of over-reach, an external fault may be regarded as an internal fault, and the protection zone will be tripped mistakenly. Both of the under-reach behavior and over-reach behavior has a negative effect to the transmission line. It is a purpose of modern protection technology to restrict the over-reach and under-reach behaviors.

FIG. 2 depicts an exemplary view of a power transmission system. Wherein, reference numeral G1 and G2 represent two power sources connected through a transmission line. Reference numeral f represents a position where ground fault occurs. Reference numeral R_{f} represents the resistance caused by the ground fault. Reference numerals M and N represent two measuring points in the transmission system. Z_{L} represents the impedance of the whole transmission line.

Reference numeral m represents per unit distance from measuring point (M) to the fault position, therefore, the impedance from f point to M point is m*Z_{L}, and the impedance from f point to N point is (1−m)*Z_{L}.

For a ground fault occurred in a transmission system as shown in FIG. 2, the voltage at bus M can be calculated with equation 1 as below.

U_{M}=m*Z_{1L}*(I_{φ}+k*I₀)+I_{f}*R_{f} (1)

Z_{1L} and Z_{0L} represent positive and zero sequence line impedance respectively. I_{Φ} represents fault phase current. I₀ represents zero sequence current. I_{f} represents zero sequence current. And, the coefficient K in equation has the expression of: k=(Z_{0L}−Z_{1L})/Z_{1L}.

The status of the transmission system and equation (1) can be expressed in the graph of FIG. 3. Wherein, the voltage of measuring point M, i.e., U_{M}, is shown as the vector 32. Vector I_{f}*R_{f} (31) represents the reactance element in the impedance plane. For a ground fault, if the system is homogeneous, the component V_{R}=I_{f}R_{f} is in phase with the current I₀. Then the calculated voltage U_{M} (32) is the real fault voltage. However, if the system is non-homogeneous, the V_{R} should be out of phase with I₀ (which have an angle difference θ therebetween), which is shown in FIG. 3.

It can be known from FIG. 3 that the calculated reactance will be over-reach or under-reach dependant on the value of θ. More specifically, there will be over-reaching trip when θ is negative, and there will be under-reaching trip when θ is positive.

In order to solve the over-reach and under-reach problem, a tile angle for reactance boundary will be preset with a possible maximum angle to avoid the relay over-reach. Conventionally, the maximum tilt angle is pre-determined, for example, as 10 or 15 degrees according to prior experience. However, by pre-determining such a constant maximum tilt angle for different situations, there are still some disadvantages.

First, when the angle θ is positive, the protection zone will have a shorter protection reach than settle reach. Second, when the fault resistance is great and with a negative angle θ, the relay still might have a mal-operation of protection zone 1 even there is a preset tilt angle. Third, the bus impedance is real-time varied based on different operation conditions, which is not completely predictable in advance. Therefore, the pre-determined constant tilt angle is not suitable for all situations.

Therefore, it is desirable to have a new scheme for the ground fault distance protection, which has a better performance when it comes to suppress over-reaching or under-reaching trip during its operation.

### BRIEF SUMMARY OF THE INVENTION

According to a first preferred embodiment of present invention, it is provided a ground distance protection method for a power transmission line, which comprises the following steps: measuring local source impedance based on fault component at both ends of the transmission line when a ground fault has occurred; sending the measured local source impedance from a first end to a second end; adjusting a protection criterion at the second end based on the measured local source impedance; and judging the ground fault as an internal fault or an external fault according to the adjusted protection criterion.

According to another aspect of the invention, the protection criterion is adjusted by combining a compensation angle with a reactance element angle in quadrilateral characteristic graph.

According to another aspect of the invention, the compensation angle is calculated based on transmission line impedance and the impedance measured at first and second ends.

According to another aspect of the invention, the method further comprises reporting an internal fault occurred within the transmission line when the combined angle of reactance element falls within a range of [−180°, 0°].

According to a second preferred embodiment of present invention, it is provided a ground distance protection controller, which comprises: a measuring unit, adapted to measure local source impedance based on fault component at both ends of a transmission line when a ground fault has occurred; a sending unit, adapted to send the measured local source impedance from a first end to a second end; an adjusting unit, adapted to adjust a protection criterion at the second end based on the measured local source impedance; and a judging unit, adapted to judge the ground fault as an internal fault or an external fault according to the adjusted protection criterion.

According to another aspect of the invention, wherein, the controller further comprises: a reporting unit, adapted to report an internal fault occurred within the transmission line when the combined angle of reactance element falls within a range of [−180°, 0°].

According to a third preferred embodiment of present invention, it is provided a ground distance protection apparatus, characterized in that it is configured to implement the protection methods described above.

According to a forth preferred embodiment of present invention, it is provided a computer program for ground protection in a power transmission line system, which computer program is loadable into an internal memory of a digital computer and comprises computer program code means to make, when said program is loaded in said internal memory, the computer execute the functions of the controller described above.

### BRIEF DESCRIPTION OF THE DRAWINGS

Further embodiments, advantages and applications of the invention are disclosed in the claims as well as in the following description, which makes reference to the accompanied FIG. 1-6, wherein:

FIG. 1 depicts a quadrilateral characteristic graph of a distance relay;

FIG. 2 depicts a schematic view of a power transmission system;

FIG. 3 depicts a calculated reactance element vector;

FIG. 4 depicts a simulation result based on unadjusted angle and the real-time compensation angle proposed in present invention;

FIG. 5 depicts a simulation result based on unadjusted angle and the preset maximum fixed compensation angle; and

FIG. 6 depicts a simulation result based on unadjusted angle and the fault-specific compensation angle in the case of a higher resistance ground fault.

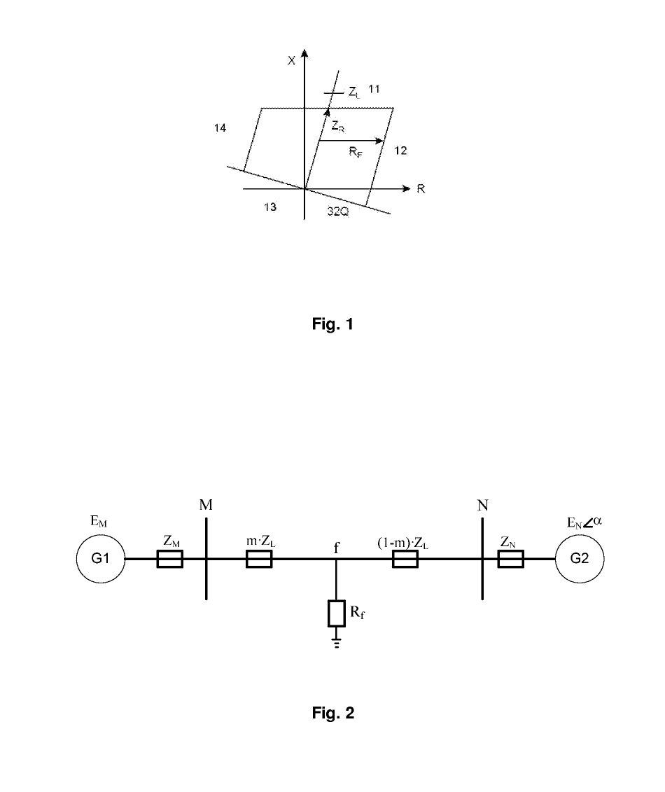

### PREFERRED EMBODIMENTS OF THE INVENTION

The protection method of present invention may comprise the following steps: first, determine whether there is a ground fault. Second, determine the fault phase. Third, calculate the local source impedance based on a fault component from the transmission line. In most situations, the fault component is a portion extracted from the total voltage and current, which consist of fault component and normal component. But in some extreme situation, the total voltage and current may comprise fault component only.

$${Z}_{M 0} = \frac{Δ {U}_{M 0}}{Δ {I}_{M 0}}$$

It should be noted that in the case of the fault was occurred at somewhere of next protection zone (i.e., an external fault), the calculated remote source impedance is negative, then the real remote source impedance can be attained by below equation, and if the fault occurred at inverse of protected line, the calculation is the same as above.

$${Z}_{N 0} = \vert \frac{Δ {U}_{N 0}}{Δ {I}_{N 0}} \vert - {Z}_{M 0} - {Z}_{0 L} \qquad ( 4 )$$

Forth, send the calculated local source impedance from local terminal to the remote terminal which locates on the other end of the protection zone. Since the change of calculated impedance is relatively slow, the impedance during fault judging period may be regarded as constant. Therefore, a synchronous channel is not necessary in present invention. Fifth, calculate the compensation angle based on the equation below.

$$θ = Angle ( \frac{{Z}_{M 0} + {Z}_{N 0} + {Z}_{0 L}}{{Z}_{N 0} + {Z}_{0 L}} )$$

Sixth, update the criterion of reactance relay α>Angle(Z−Zₛₑₜ)>β according to the compensation angle calculated during fault period:

α>Angle(Z−Zₛₑₜ)−θ>β

Then, it can be determined from above criterion that whether the fault is an external one or an internal one. The steps will be explained in the following paragraphs.

For the power transmission system as shown in FIG. 2, the zero sequence current is detected for determining whether there is a fault occurred in the transmission line. When the measured zero sequence current exceeds a threshold, it can be inferred that a fault is occurred somewhere at the transmission line. More specifically, the zero sequence current at each phase may be measured for determining on which phase the fault is occurred.

When it is determined that a single-phase ground fault occurred in the transmission line L, the real source zero-sequence impedance at measuring points M and N can be calculated with equation (2) in real time. The impedances at both measuring points are calculated based on the fault component.

$${Z}_{M 0} = \frac{Δ {U}_{M 0}}{Δ {I}_{M 0}} , \\ {Z}_{N 0} = \frac{Δ {U}_{N 0}}{Δ {I}_{N 0}} \qquad ( 2 )$$

In one preferred embodiment, the calculated real time impedance for one measuring point N, e.g. Z_{N0}, is sent to the other terminal (the remote measuring point M). Then the relay at the other terminal may receive and store this impedance. The received impedance would be used for calculating the compensation angle as described below. Since the change rate of local source impedance is low (in compare with the fault period and sampling period), it is not necessary to send the calculated real time impedance from N to M frequently. Therefore, a synchronous communication line is not a necessity in the solution of present invention.

However, in another preferred embodiment, the impedance is calculated at every sampling period in real time. And all calculated real time impedance can be sent to the remote terminal sequentially at each sampling period. The remote terminal then calculates the compensation angle based on the real time impedance received at different sampling period.

For the relay at point M's end, the maximum differential angle between measured zero-sequence current and fault current can be calculated by equation (3) below (I_{f} leading to I₀).

$$θ = Angle ( \frac{{Z}_{M 0} + {Z}_{N 0} + {Z}_{0 L}}{{Z}_{N 0} + {Z}_{0 L}} ) \qquad ( 3 )$$

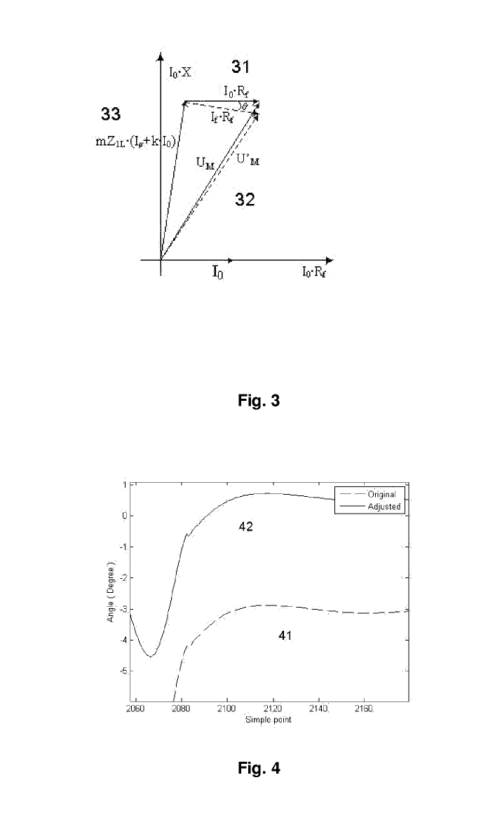

In equation (3), Z_{M0} represents zero sequence line impedance at point M; Z_{N0} represents zero sequence line impedance at point N; and Z_{0L} represents zero sequence line impedance. In present invention, the fault specific compensation angle θ (which is calculated with respect to different fault situations) instead of a fixed angle (10-15 degrees) will be used to adjust the reactance element in the impedance plane in FIG. 3.

Based on the principle of reactance relay, for an internal fault, the calculated angle between measured impedance and set impedance should be within the range of [−180°, 0°]. Otherwise, the fault shall be recognized as an external fault. In this regard, the criterion for determining the internal or external fault may be expressed as the equation below (5):

γ>Angle(Z−Zₛₑₜ)>β (5)

Wherein, Z represents the impedance measured as line impedance, and Zₛₑₜ represents the set line impedance. In the discussion and calculation of present invention, the value of set line impedance shall be 80% of overall line impedance.

Based on the compensation angle θ, the revised criterion is shown as below equation (6):

γ>Angle(Z−Zₛₑₜ)−θ>β (6)

By this revised criterion, the ground distance relay can get a better performance with respect to a non-homogeneity system. That is, the recognition of fault type is more accurate, and the mal-trip activity will be significantly reduced as compared with conventional technology.

The inventors have made simulations to compare the fault type determined by the criterion proposed in present invention and conventional criterion.

### Example 1

The transmission system used for simulation is the same as that of FIG. 2. The system condition is only different in that: Z_{M0} and Z_{N0} are not the same, and all of two impedance angles are leading to that of Z_{0L}. The system parameters for the simulation are listed as below:

Source voltage: Uₘ=U_{N}=220 kV, ∠α=−20;
Source impedance: Z_{M}=35∠85 and Z_{N}=25∠80. In order to simplify the simulation, it is assumed that positive sequence impedance equals to zero/negative sequence impedances.
Line: Length=100 km, and other line parameters are:
R₁=1.27e−5(Ω/m), R₀=2.729e−4(Ω/m), X₁=2.68e−4(Ω/m), X₀=8.4e−4(Ω/m),

The reach of zone 1 of relay is set as 80% (set range) of the overall transmission line. That is, the reach of zone 1 is set with a 20 km allowance to avoid over-reach. And, the sampling frequency of relay is set as 4000 Hz.

Taken the relay at M side as example, and assumed that there is an external phase-A ground fault occurred. It is further assumed that the fault point is at position of 90% length of the whole transmission line. The resistance of the load is 30 ohm; and the fault takes place at 0.5 second after the beginning of sampling process. In view of the 4000 Hz sampling frequency, the fault takes place at the 2000^{th} sample point in the FIG. 4.

Since the reach of zone 1 is set as 80% length of the whole transmission line, the fault point at 90% length of the whole transmission line is, actually, an external fault with respect to zone 1. Based on above parameters, the simulation is operated to find out the judgment of conventional and present criterions.

FIG. 4 shows the difference of the calculated compensation angle between the scheme proposed in present invention and the scheme without adjusting angle of reactance element. As mentioned above, when the angle difference falls within the range of [−180°, 0°], the ground protection scheme will report an internal fault occurred in the protected zone 1, and the relay will trip for the purpose of protection. When the angle difference exceeds said range, the ground protection scheme will recognized the fault as an external one, and therefore will not trip in the protected zone 1.

It can be seen from FIG. 4 that based on the angle without any adjustment (as indicated by dashed line 41), the relay will make a wrong decision (recognize the external fault as inner fault) after the fault has occurred for about 20 ms (i.e., at the 2080^{th} sample point). That is, after one cycle of the AC transmission, the zone 1 will be tripped due to the wrong judgment.

However, based on the compensation angle calculated with respect to the occurred fault, the angle difference will exceed the upper limit of the range (0°) at sample point around 2090. Therefore the relay will give out a correct judgment for external fault (as indicated by solid line 42).

It is clear that the scheme without reactance angle adjustment is not suitable of a variety of system operation condition.

From the simulation example above, the fault-specific adjusted compensation angle is superior to the scheme without angle adjustment.

### Example 2

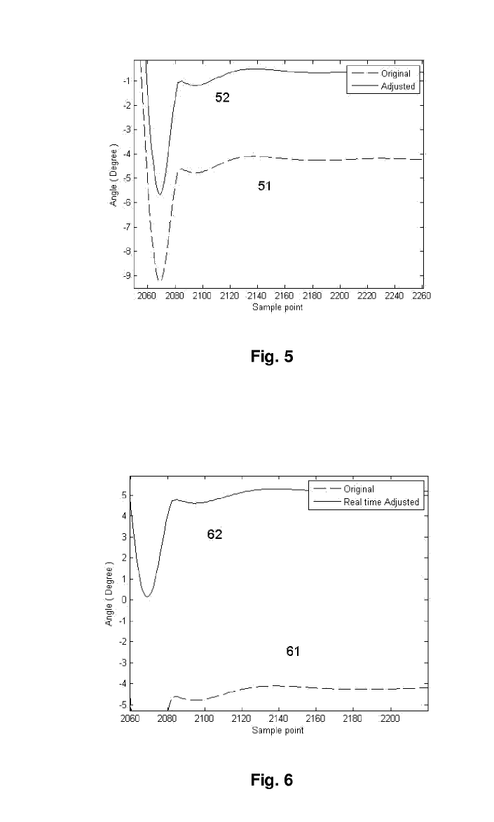

As an example, another simulation example is shown in FIG. 5. In this scenario, the position of fault point is the same as above example 1. Regarding the system parameter, the only difference is that the source impedance of M end is set as a value higher than that of example 1, i.e., Z′_{M}=65∠65°. In this example, the angle of reactance element in impedance plane is adjusted by using a pre-settable fixed compensation angle based on prior experience (i.e., the angle adjustment adopted by conventional technology).

It can be seen from FIG. 5 that even if the reactance angle is compensated with a maximum fixed value, the misjudgment can not be avoided. In this example, it is already assumed that an external fault is occurred at sample point 2000. However, both the original (unadjusted) and adjusted angle difference curves 51 and 52 shows that the angle difference is within the range of [−180°, 0° ]. That is, the relay recognizes that an internal fault has occurred in the protecting zone 1 even if the angle is adjusted by a maximum value. That is, the conventional scheme is not effective in the case of a higher resistance fault occurred.

### Example 3

For the same system parameters as above example 2, if the protection scheme uses a fault-specific calculated Z_{M} and Z_{N} based on the fault component, the relay of M side will give out a correct decision.

As shown in FIG. 6, the adjusted angle difference curve 62 (solid line) shows that the angle difference exceeds the range of [−180°, 0°] from, at least, sample point 2060. Therefore, the scheme proposed by present invention will make correct judgment for the situation of high resistance.

The methods and schemes of present invention may be implemented as software run on a digital computer, or as a hard-wired implementation using techniques such as EPROM etc. In the case of implementing the proposed method as hardware, it is clear to those skilled in the art that each step mentioned above for identifying fault, calculating compensation angle, etc, may correspond to a separate hardware unit. For example, a determination unit may be provided to judge whether there is a fault occurred in the transmission line, and in which phase the fault is occurred. A measuring unit may be provided to measure the impedance. A communicating unit may be provided to send and receive the measured impedance from one end to the other end. A processing unit may be provided to calculate the compensation angle based on the received impedance. And a judging unit may be provided to output a trip signal when the processing unit finds the angle difference falls within the range.

Alternatively, all the steps/functions may be implemented by an integrated processor in the relay. In which, all above separate units are combined together to perform the proposed protection method. All available semiconductor techniques may be used to produce such hardware.

For those skilled in the art, various modifications can be conceived without departing from the scope of present invention. For example, all the other well-known fault detection schemes can be applied in present invention.

The invention intends to include all possible modifications within the proposed concept, and the scope of the invention should be defined by the accompanied claims instead of above detailed embodiments.

1. A ground distance protection method for a power transmission line, comprising:
measuring a local source impedance based on fault component at both ends of the transmission line when a ground fault has occurred;
sending the measured local source impedance from a first end to a second end;
adjusting a protection criterion at the second end based on the measured local source impedance; and
judging the ground fault as an internal fault or an external fault according to the adjusted protection criterion.

2. The protection method according to claim 1, wherein,
the protection criterion is adjusted by combining a compensation angle with a reactance element angle in quadrilateral characteristic graph.

3. The protection method according to claim 2, wherein,
the compensation angle is calculated based on a transmission line impedance and the impedance measured at first and second ends.

4. The protection method according to claim 2, wherein, it further comprises:
reporting an internal fault occurred within the transmission line when the combined angle of reactance element falls within a range of [−180°, 0°].

5. A ground-distance protection controller, comprising:
a measuring unit, adapted to measure a local source impedance based on fault component at both ends of a transmission line when a ground fault has occurred;
a sending unit, adapted to send the measured local source impedance from a first end to a second end;
an adjusting unit, adapted to adjust a protection criterion at the second end based on the measured local source impedance; and
a judging unit, adapted to judge the ground fault as an internal fault or an external fault according to the adjusted protection criterion.

6. The protection controller according to claim 5, wherein,
the protection criterion is adjusted by combining a compensation angle with a reactance element angle in quadrilateral characteristic graph.

7. The protection controller according to claim 6, wherein,
the compensation angle is calculated based on transmission line impedance and the impedance measured at first and second ends.

8. The protection controller according to claim 6, wherein, it further comprises:
a reporting unit, adapted to report an internal fault occurred within the transmission line when the combined angle of reactance element falls within a range of [−180°, 0°].

9. A ground distance protection apparatus, characterized in that it is configured to implement the protection method according to claim 1.

10. A computer program for ground protection in a power transmission line system, which computer program is loadable into an internal memory of a digital computer and comprises computer program code means to make, when said program is loaded in said internal memory, the computer execute the functions of the controller according to claim 5.

11. The protection method according to claim 3, wherein, it further comprises:
reporting an internal fault occurred within the transmission line when the combined angle of reactance element falls within a range of [−180°, 0°].

12. The protection controller according to claim 7, wherein, it further comprises:
a reporting unit, adapted to report an internal fault occurred within the transmission line when the combined angle of reactance element falls within a range of [−180°, 0°].
